(19) United States
(12) Patent Application Publication
(10) Pub. No.: US 2016/0068748 A1
(43) Pub. Date: Mar. 10, 2016

(54) EU-DOPED SRI2 SINGLE CRYSTAL, RADIATION DETECTOR, AND METHOD FOR PRODUCING EU-DOPED SRI2 SINGLE CRYSTAL

(71) Applicant: Union Materials Inc., Kitasoma-gun (JP)

(72) Inventor: Shiro SAKURAGI, Ibaraki (JP)

(21) Appl. No.: 14/845,811

(22) Filed: Sep. 4, 2015

(30) Foreign Application Priority Data
Sep. 5, 2014 (JP) 2014-180945

(51) Int. Cl. C09K 11/77; C30B 29/12; G01T 1/202; C30B 25/02

(52) U.S. Cl. CPC C09K 11/7733; C30B 25/02; C30B 29/12; G01T 1/2023

(57) ABSTRACT

An Eu-doped SrI₂ single crystal having a fluorescence spectrum in which the intensity ratio of defect-related luminescence at around 550 nm to Eu-derived luminescence at around 430 nm is 1% or less, the fluorescence spectrum being measured at room temperature using ultraviolet light having a wavelength of 193 nm as excitation light, and a radiation detector that includes a scintillator that includes the Eu-doped SrI₂ single crystal.

This application claims priority to Japanese Patent Application No. 2014-180945 filed on Sep. 5, 2014, the entire contents of which are incorporated herein by reference.

### BACKGROUND

The present invention relates to an Eu-doped SrI₂ single crystal that is suitable as a scintillator used for a radiation detector, a radiation detector that includes the Eu-doped SrI₂ single crystal as a scintillator, and a method for producing the Eu-doped SrI₂ single crystal.

Non-Patent Documents 1 to 3 disclose an Eu-doped SrI₂ single crystal as a material that is suitable as a scintillator used for a radiation detector.

### Non-Patent Document

Non-Patent Document 1: B. W. Sturm et al., Characteristics of Un-doped and Europium-doped SrI₂ Scintillator Detectors, IEEE Nuclear Science Symposium Conference Record, 2011, pp. 7-11

Non-Patent Document 2: L. A. Boatner et al., Bridgman growth of large SrI₂:Eu²⁺ single crystals: A high-performance scintillator for radiation detection applications, Journal of Crystal Growth, 2013, Vol. 379, pp. 63-68

Non-Patent Document 3: P. R. Beck et al., Strontium Iodide Instrument Development for Gamma Spectroscopy and Radioisotope Identification, Proc. SPIE Vol. 9213 92130N

Non-Patent Document 1 discloses that the energy resolution of an un-doped SrI₂ single crystal with respect to 662 keV radiation is 5.3%, and the energy resolution of an Eu-doped SrI₂ single crystal with respect to 662 keV radiation is less than 3%.

FIG. 1 illustrates the fluorescence spectrum 11 of a known un-doped SrI₂ single crystal and the fluorescence spectrum 12 of a known Eu-doped SrI₂ single crystal disclosed in Non-Patent Document 1. Non-Patent Document 1 is silent about the details of the measurement conditions. The known un-doped SrI₂ single crystal has a broad luminescence band at around 550 nm. It is considered that this broad luminescence band is due to crystal defects.

On the other hand, the known Eu-doped SrI₂ single crystal has a sharp and strong luminescence band at around 430 nm. This sharp and strong luminescence band is due to Eu, and the luminescence intensity is higher than 3300 (arbitrary unit). It is considered that the energy resolution of the Eu-doped SrI₂ single crystal is improved by the strong Eu-derived luminescence.

However, the known Eu-doped SrI₂ single crystal also has a broad defect-related luminescence band at around 550 nm. The intensity of luminescence at around 550 nm is estimated to be about 200 (arbitrary unit), and the intensity ratio of luminescence at around 550 nm to luminescence at around 430 nm is 5% or more.

Non-Patent Document 1 does not disclose the details of the method for producing an Eu-doped SrI₂ single crystal. Non-Patent Document 2 discloses a method for producing an Eu-doped SrI₂ single crystal that includes charging an ampule with an SrI₂ raw material to which EuI₂ is added, drying (dehydrating) the raw material under vacuum, sealing the ampule under vacuum, and effecting crystal growth using a

Bridgman method. Note that some of the authors of Non-Patent Document 2 are the same as those of Non-Patent Document 1.

It is considered that an Eu-doped SrI₂ single crystal that is grown under vacuum includes defects due to desorption (removal or elimination) of I⁻, incorporation of water, and the like. It is considered that the energy is consumed by defect-related luminescence at around 550 nm, and the intensity of Eu-derived luminescence at around 430 nm decreases.

FIG. 2 illustrates the fluorescence spectrum of an Eu-doped SrI₂ single crystal disclosed in Non-Patent Document 3 (excitation light: β-rays). Note that Non-Patent Document 3 was published on Sep. 9, 2014 (i.e., published after the filing date of Japanese Patent Application No. 2014-180945) through the Internet. Some of the authors of Non-Patent Document 3 are the same as those of Non-Patent Documents 1 and 2. The intensity ratio of luminescence at around 550 nm (intensity: 38 (arbitrary unit)) to luminescence at around 430 nm (intensity: 2180 (arbitrary unit)) of the Eu-doped SrI2 single crystal disclosed in Non-Patent Document 3 is 1.7%.

### SUMMARY

According to one embodiment of the invention, there is provided an Eu-doped SrI₂ single crystal having a fluorescence spectrum in which an intensity ratio of defect-related luminescence at around 550 nm to Eu-derived luminescence at around 430 nm is 1% or less, the fluorescence spectrum being measured at room temperature using ultraviolet light having a wavelength of 193 nm as excitation light.

According to another embodiment of the invention, a radiation detector includes a scintillator that includes the Eu-doped SrI₂ single crystal, and a photoelectric converter that converts scintillation light from the scintillator into an electrical signal.

According to another embodiment of the invention, there is provided a method for producing the above Eu-doped SrI₂ single crystal, the method comprising subjecting a raw material to reactive-gas atmosphere processing (RAP), and effecting growth of the Eu-doped SrI₂ single crystal in a halogen-containing gas atmosphere using the raw material, the RAP including treating the raw material with a halogen-containing gas, and discharging a reactive gas, and the raw material including strontium iodide and europium iodide.

### BRIEF DESCRIPTION OF THE DRAWINGS

FIG. 1 illustrates the fluorescence spectrum of a known un-doped SrI₂ single crystal and the fluorescence spectrum of a known Eu-doped SrI₂ single crystal disclosed in Non-Patent Document 1.

FIG. 2 illustrates the fluorescence spectrum of an Eu-doped SrI₂ single crystal disclosed in Non-Patent Document 3 (excitation light: β-rays).

FIG. 3 schematically illustrates the structure of a radiation detector.

FIG. 4 illustrates the fluorescence spectrum of an Eu-doped SrI₂ single crystal according to one embodiment of the invention.

FIG. 5 illustrates the fluorescence spectrum of an Eu-doped SrI₂ single crystal at around 550 nm (magnification: 100).

### DETAILED DESCRIPTION OF THE INVENTION

### Description of Exemplary Embodiments

The invention was conceived in view of the above situation. An object of the invention is to provide an Eu-doped SrI₂ single crystal for which broad defect-related luminescence at around 550 nm is reduced, a radiation detector that includes a scintillator that includes the Eu-doped SrI₂ single crystal, and a method for producing the Eu-doped SrI₂ single crystal.

According to one embodiment of the invention, there is provided an Eu-doped SrI₂ single crystal having a fluorescence spectrum in which an intensity ratio of defect-related luminescence at around 550 nm to Eu-derived luminescence at around 430 nm is 1% or less, the fluorescence spectrum being measured at room temperature using ultraviolet light having a wavelength of 193 nm as excitation light.

Specifically, the Eu-doped SrI₂ single crystal is characterized in that broad defect-related luminescence at around 550 nm is reduced. Since the energy that is normally consumed by defect-related luminescence is consumed by Eu-derived luminescence at around 430 nm, it is considered that the intensity of luminescence at around 430 nm increases.

According to another embodiment of the invention, a radiation detector includes a scintillator that includes the Eu-doped SrI₂ single crystal, and a photoelectric converter that converts scintillation light from the scintillator into an electrical signal.

It is considered that the intensity of luminescence from the scintillator at around 430 nm increases, and the energy resolution of the radiation detector is improved.

According to another embodiment of the invention, there is provided a method for producing the above Eu-doped SrI₂ single crystal, the method comprising subjecting a raw material to reactive-gas atmosphere processing (RAP), and effecting growth of the Eu-doped SrI₂ single crystal in a halogen-containing gas atmosphere using the raw material, the RAP including treating the raw material with a halogen-containing gas, and discharging a reactive gas, and the raw material including strontium iodide and europium iodide.

When the raw material that includes strontium iodide and europium iodide is subjected to RAP that includes treating the raw material with a halogen-containing gas, and discharging the reactive gas, water included in the raw material is converted into a compound that does not adversely affect the Eu-doped SrI₂ single crystal. When the Eu-doped SrI₂ single crystal is grown in a halogen-containing gas atmosphere using the raw material, a situation in which I⁻ is removed from the raw material is suppressed (i.e., a defect is not introduced into the crystal). Specifically, broad defect-related luminescence at around 550 nm is reduced.

Exemplary embodiments of the invention are described below with reference to the drawings.

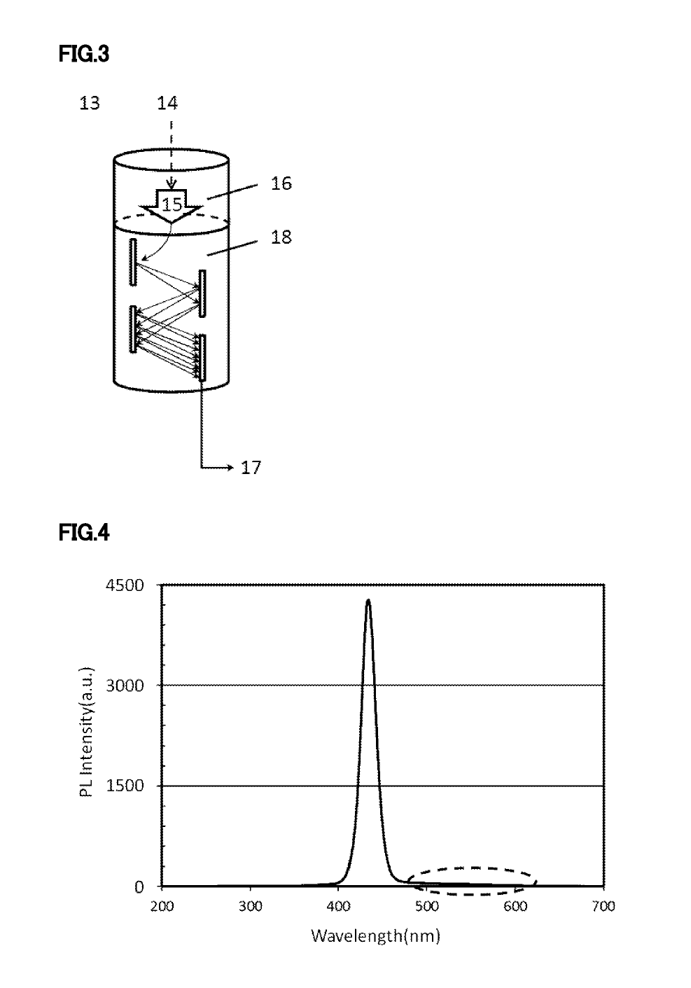

FIG. 3 schematically illustrates the structure of a radiation detector 13. The radiation detector 13 includes a scintillator 16 that converts incident radiation 14 into scintillation light 15. The material used as the scintillator 16 is selected taking account of the object and the application. An Eu-doped SrI₂ single crystal is known as a typical material used for γ-rays.

The radiation detector 13 includes a photoelectric converter 18 that converts the scintillation light 15 from the scintillator 16 into an electrical signal 17, and outputs the electrical signal 17. A photomultiplier, a photodiode, a multi-pixel photon counter (MPPC), or the like may be used as the photoelectric converter 18. In FIG. 3, the photoelectric converter 18 is configured as a photomultiplier. Note that a known photoelectric converter may be used as the photoelectric converter 18 as long as the photoelectric converter has the desired sensitivity.

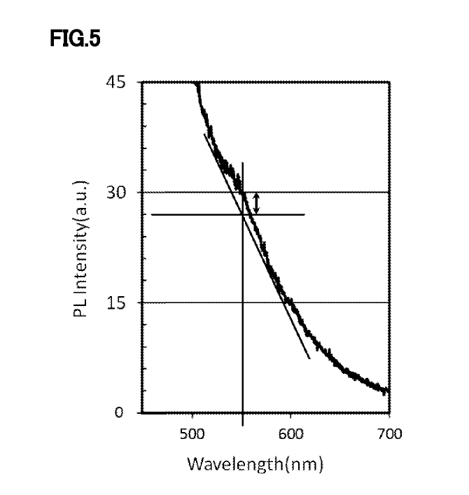

An Eu-doped SrI₂ single crystal may be used as the scintillator 16 included in the radiation detector 13. FIG. 4 illustrates the fluorescence spectrum of a 1.5 mol % Eu-doped SrI₂ single crystal according to one embodiment of the invention. ArF excimer laser light (wavelength: 193 nm) was used as excitation light. The fluorescence spectrum was measured at room temperature.

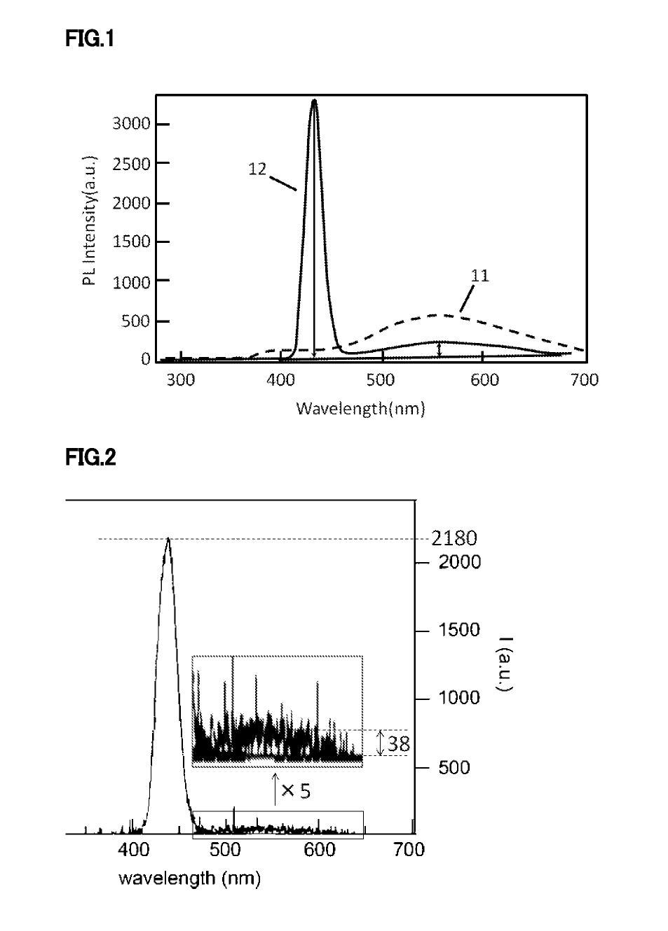

The fluorescence spectrum includes the spectrum of Eu-derived luminescence and the spectrum of defect-related luminescence (see the fluorescence spectrum 12 of a known Eu-doped SrI₂ single crystal illustrated in FIG. 1). In FIG. 4, the intensity of Eu-derived luminescence at around 430 nm is higher than 4,200 (arbitrary unit). On the other hand, the intensity of defect-related luminescence at around 550 nm is low.

FIG. 5 illustrates the spectrum obtained by enlarging the spectrum in FIG. 4 that is enclosed by the broken line in the vertical axis direction (magnification: 100). The intensity of defect-related luminescence at around 550 nm was estimated using the spectrum illustrated in FIG. 5. When the base of Eu-derived luminescence at around 430 nm is approximated using a straight line, the height from the straight line represents the intensity of defect-related luminescence.

The intensity of defect-related luminescence is estimated to be about 3 (arbitrary unit). Specifically, the intensity ratio of defect-related luminescence at around 550 nm to Eu-derived luminescence at around 430 nm in the fluorescence spectrum (excitation light: ultraviolet light (wavelength: 193 nm)) of the Eu-doped SrI₂ single crystal according to one embodiment of the invention is 0.1% or less.

A method for producing the Eu-doped SrI₂ single crystal is described below.

Strontium carbonate (SrCO₃) (purity: 4N), europium oxide (Eu₂O₃) (purity: 3N), and hydro-iodic acid (HI+H₂O) are reacted, and the reaction product is dried (dehydrated) under vacuum to prepare a raw material. The Eu concentration is adjusted by adjusting the amounts of strontium carbonate and europium oxide. When adjusting the Eu concentration to 1.5 mol %, the molar ratio of strontium carbonate to europium oxide is adjusted to 99.234:0.766.

A quartz tube (ampule) is charged with the raw material, and the raw material is dried under vacuum inside an electric furnace. For example, the raw material is dried at 200° C. for 12 hours. The drying time is adjusted taking account of the amount of the raw material. After the addition of silicon tetra-iodide to the raw material (that has been dried under vacuum), the mixture is heated to about 450° C. to effect the following reaction.

SiI₄+2H₂O→SiO₂+4HI

Water that has not been removed by vacuum drying is thus converted into a compound that does not adversely affect the crystal. Water is removed from the raw material by discharging a reactive gas. The reactive gas includes a halogen. For example, I₂, HI, CI₄, CH₂I₂, or the like may be used. A process that removes water from the raw material using a halogen-containing gas (e.g., iodine-containing gas) has been used when producing a single crystal of a metal halide (i.e., a compound of fluorine, chlorine, bromine, or iodine and a metal), and is referred to as “reactive-gas atmosphere processing (RAP)”.

The raw material that has been subjected to RAP is put in a quartz tube under an iodine-containing atmosphere, and the quartz tube is sealed. The atmosphere includes a halogen. For example, SiI₄, I₂, HI, CI₄, CH₂I₂, or the like may be used. When the atmosphere includes a halogen, a situation in which I⁻ is removed (eliminated) from the raw material during crystal growth is suppressed. Crystal growth is effected by a vertical Bridgman method using a two-zone furnace to obtain an Eu-doped SrI₂ single crystal. The growth temperature gradient is set to 15° C./cm, and the growth rate is set to 1 mm/hour.

Defect-related luminescence at around 550 nm is observed to only a small extent in the fluorescence spectrum of the resulting Eu-doped SrI₂ single crystal (see FIG. 4).

It is desirable that the intensity of defect-related luminescence at around 550 nm be low. The intensity ratio of defect-related luminescence at around 550 nm to Eu-derived luminescence at around 430 nm in the fluorescence spectrum (excitation light: ultraviolet light (wavelength: 193 nm)) is preferably 3% or less, more preferably 1% or less, and still more preferably 0.1% or less. Specifically, since the energy that is normally consumed by defect-related luminescence is consumed by Eu-derived luminescence at around 430 nm, the intensity of luminescence at around 430 nm increases, and the energy resolution of the radiation detector is improved.

The method for producing the Eu-doped SrI₂ single crystal according to one embodiment of the invention differs from a known method for producing an Eu-doped SrI₂ single crystal in that the method according to one embodiment of the invention includes RAP, and effects crystal growth in a halogen-containing gas atmosphere. The intensity of defect-related luminescence at around 550 nm can be adjusted by changing the production conditions.

The intensity ratio of defect-related luminescence at around 550 nm to Eu-derived luminescence at around 430 nm of the Eu-doped SrI₂ single crystal disclosed in Non-Patent Document 3 (which was published after the filing date of Japanese Patent Application No. 2014-180945) is 1.7%. The amount of defects included in the Eu-doped SrI₂ single crystal produced using the method according to one embodiment of the invention is significantly reduced as compared with the Eu-doped SrI₂ single crystal disclosed in Non-Patent Document 3.

Although only some embodiments of the present invention have been described in detail above, those skilled in the art will readily appreciate that many modifications are possible in the embodiments without materially departing from the novel teachings and advantages of this invention. Accordingly, all such modifications are intended to be included within scope of this invention.

What is claimed is:

1. An Eu-doped SrI₂ single crystal having a fluorescence spectrum in which an intensity ratio of defect-related luminescence at around 550 nm to Eu-derived luminescence at around 430 nm is 1% or less, the fluorescence spectrum being measured at room temperature using ultraviolet light having a wavelength of 193 nm as excitation light.

2. A radiation detector comprising a scintillator that includes the Eu-doped SrI₂ single crystal as defined in claim 1, and a photoelectric converter that converts scintillation light from the scintillator into an electrical signal.

3. A method for producing the Eu-doped SrI₂ single crystal as defined in claim 1, the method comprising subjecting a raw material to reactive-gas atmosphere processing (RAP), and effecting growth of the Eu-doped SrI₂ single crystal in a halogen-containing gas atmosphere using the raw material, the RAP including treating the raw material with a halogen-containing gas, and discharging a reactive gas, and the raw material including strontium iodide and europium iodide.
